(19) United States
(12) Patent Application Publication
(10) Pub. No.: US 2009/0056797 A1
(43) Pub. Date: Mar. 5, 2009

(54) Photovoltaic Thin-Film Solar Cell and Method Of Making The Same

(75) Inventors: Allen M. Barnett, Landenberg, PA (US); Jeffrey Barnett, Landenberg, PA (US); Kevin Allison, Goleta, CA (US); Jerome S. Culik, Nottingham, PA (US)

Correspondence Address: KILYK & BOWERSOX, P.L.L.C., 400 HOLIDAY COURT, SUITE 102, WARRENTON, VA, 20186, US

(73) Assignee: BLUE SQUARE ENERGY INCORPORATED, North East, MD (US)

(21) Appl. No.: 12/196,501

(22) Filed: Aug. 22, 2008

Related U.S. Application Data
(60) Provisional application No. 60/968,443, filed on Aug. 28, 2007.

(51) Int. Cl. H01L 31/042; H01L 31/0232; H01L 31/18

(52) U.S. Cl. 136/255; 136/256; 438/72; 257/E31.127

(57) ABSTRACT

A photovoltaic device having a front and back orientation and comprising: a crystalline substrate having a resistivity greater than about 0.01 ohm-cm; and an epitaxy thin-film layer in front of said substrate, said thin-film layer contacting said substrate in at least one region to define a p-n junction.

This application claims the benefit under 35 U.S.C. §119(e) of prior U.S. Provisional Patent Application No. 60/968,443, filed Aug. 28, 2007, which is incorporated in its entirety by reference herein.

### BACKGROUND

The photovoltaic (PV) cell industry has followed essentially two paths bulk silicon, and, more recently, thin-film crystalline silicon. Single-crystal and multi-crystalline bulk silicon solar cells have demonstrated high efficiency and long operating lifetimes, but have been too costly for many applications due to their high material demands and low manufacturing throughput. Thin-film technologies were developed as a means of substantially reducing the cost of photovoltaic (PV) systems. Thin-film processes are appealing due to reduced materials consumption and the potential for high-throughput production. They are also amenable to monolithic array designs, thus reducing costs of creating modules. Unfortunately, thin-film crystalline silicon solar cells have generally failed to demonstrate the degree of efficiency or reliability found in bulk crystalline silicon solar cells.

In the 1980s, the technology evolved to hybrid approaches in which thin-films of silicon were deposited on low-cost substrates. This approach combines the high efficiency and reliability associated with bulk crystalline silicon solar cells with the low-cost potential of thin-film deposition technology. U.S. Pat. No. 4,571,448, granted to Allen Barnett (also present applicant), discloses a seminal design for a thin-film crystalline silicon photovoltaic solar cell on a low-cost substrate. This patent realized that incorporating light-trapping features in thin-film solar cells not only ameliorates inefficiencies previously expected with thin-film silicon solar cells, but also enhances performance of the thin-film cells beyond traditional bulk silicon approaches. Many of the expected advantages of a thin-film silicon solar cell, such as high photogenerated currents due to light-trapping, high voltages due to higher doping levels, monolithic interconnection, reduced sensitivity to impurities and crystal defects, and enhanced gettering potential, have been demonstrated, but only singularly in various experimental devices.

Unfortunately, the useful and synergistic combination of these features in a cost-effective, production technology has eluded the industry. Applicant has previously recognized, in PCT Published Application No. WO2006/29834, that the problems encountered in achieving this objective tended to involve difficulties in producing thin layers of high quality silicon on low-cost substrates. This reflects conventional wisdom that the key to a robust and effective PV cells lies in the quality of the thin film.

Therefore, there is a need to provide a thin film crystalline silicon PV cell design that not only offers the benefits of thin-film and light trapping technologies, but also is robust and inexpensive. The present invention fulfills this need among others.

### SUMMARY OF INVENTION

The present invention provides a low-cost, robust, high-efficiency PV cell that overcomes the shortcomings of the prior art by accommodating the defects of the thin-film layer, rather than attempting to eliminate them. Specifically, applicant has discovered that the performance of a thin-film PV cell can be improved remarkably and surprisingly by increasing the resistance of the substrate to prevent defects in the thin-film layer from causing shunts. In other words, the substrate is made “fault tolerant” to accommodate the thin-film layer. This is a significant departure from conventional approaches of improving the quality of the thin films, and recognizes instead that a commercially-viable PV cell must be capable of high-volume production in which defects in the thin-film layer, such as manufacturing variances, voids, and impurities, are unavoidable as a practical matter. Furthermore, the detrimental effects of these defects would likely increase as the layer becomes thinner to enhance performance or less uniform due to high-volume manufacturing (i.e., relaxed tolerances). The substrate of the present invention, however, allows this enhanced performance and high-volume manufacturing to be realized while accommodating the associated defects.

This enhanced performance more than compensates for the reduced voltage across the cell due to the substrate's increased resistivity. That is, although increasing the substrate's resistivity tends to diminish voltage across the PV cell, applicant has found that significant fault tolerance can be realized without a corresponding decrease in solar cell voltage. Typically, substrate resistivity can be increased significantly without a precipitous decline in voltage.

In addition to improved performance, the PV cell of the present invention also provides significant cost savings. Specifically, the specified resistivity of the substrate generally correlates to a less pure substrate. This relatively impure subtract material is less expensive since less refining of the semiconductor is required. For example, the desired resistivity may correspond to a boron concentration in silicon of greater than 10 ppm, which is relatively impure and thus readily achievable using inexpensive purification processes. Not only is the material cost low, but also the substrate can be manufactured using casting processes, rather than complex and slow Czochralski or Float Zone ingot formation processes. The thin-film layer also is less expensive since it can be made thinner, thus reducing processing time and material requirements. Additionally, the fault tolerance of the substrate allows the thin-film layer to be formed with processes that are quicker and less expensive even though they may tend to introduce more defects (e.g., manufacturing variances/defects/crystal boundaries) compared to traditional epitaxial vapor deposition techniques.

The performance of the PV cell of the present invention is further enhanced by the addition of light-capturing elements, such as reflectors and textured surfaces, and by concentrating the charge carriers using barrier layers to reduce the size of the p-n junctions. To this end, applicant recognizes that epitaxial lateral overgrowth (ELO) techniques, which were developed in the production of microelectronic devices, may be applied to PV cells to enable the thin-film layer to be grown over planar reflective or barrier layers on the substrate. By using ELO processes to incorporate reflective surfaces and other light-capturing elements into a PV cell, enhancements, such as high photogenerated currents, improved photon conversion, and enhanced gettering potential, are synergistically realized.

Accordingly, one aspect of the present invention is a PV cell having a thin-film, epitaxially grown layer overlaying a fault resistant substrate. In one embodiment, the cell comprises a crystalline substrate having a resistivity greater than about 0.02 ohm-cm, and an epitaxy thin-film layer on said substrate, said thin-film layer contacting said substrate in at least one region to define a p-n junction. In one embodiment, the PV cell has improved efficiency through the use of reflectors and other light capturing optics. For example, reflectors between the substrate and the thin-film layer improve the conversion of photons to charge carriers which can be transported across the p-n junction.

Another aspect of the present invention is a method of manufacturing a PV cell by epitaxially forming a thin-film layer on a fault-tolerant substrate. In one embodiment, the method comprises providing a crystalline substrate having a resistivity greater than about 0.02 ohm-cm, and epitaxially depositing a thin-film layer over at least a portion of said substrate. In one embodiment, the method further comprises depositing a reflector between the substrate and the thin-film layer and using epitaxial lateral overgrowth processes to cover the reflector with the thin-film layer.

### BRIEF DESCRIPTION OF DRAWINGS

FIG. 1 shows a perspective, schematic view of an embodiment of a photovoltaic device.

FIG. 1a is a detailed view of a portion of the device of FIG. 1.

FIG. 2 shows a plan view of an embodiment of a photovoltaic device.

FIG. 3 shows a cross section of a portion of the device of claim 2.

FIGS. 4A-4F show a series of cross-sections illustrating a process for making a photovoltaic device.

### DETAILED DESCRIPTION OF INVENTION

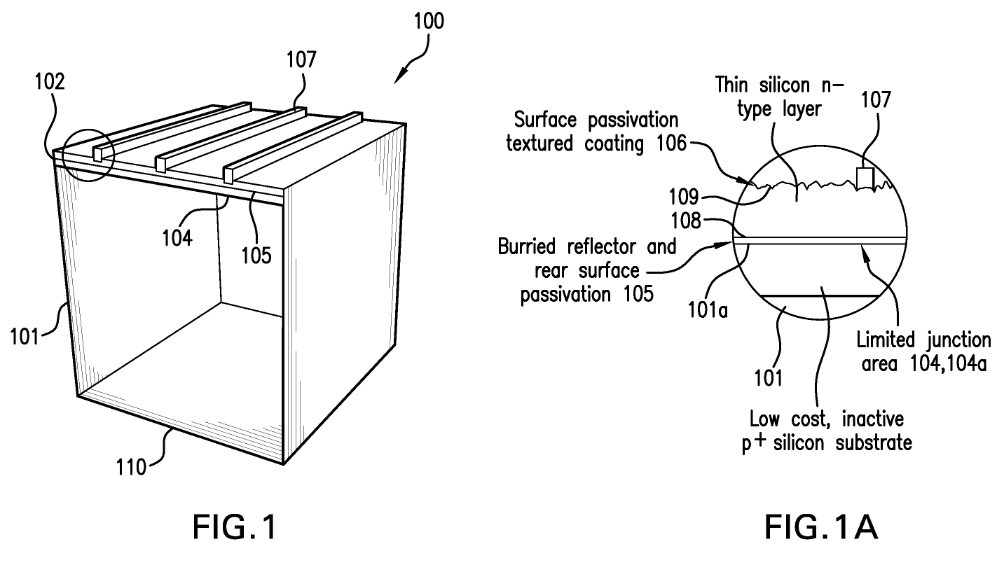

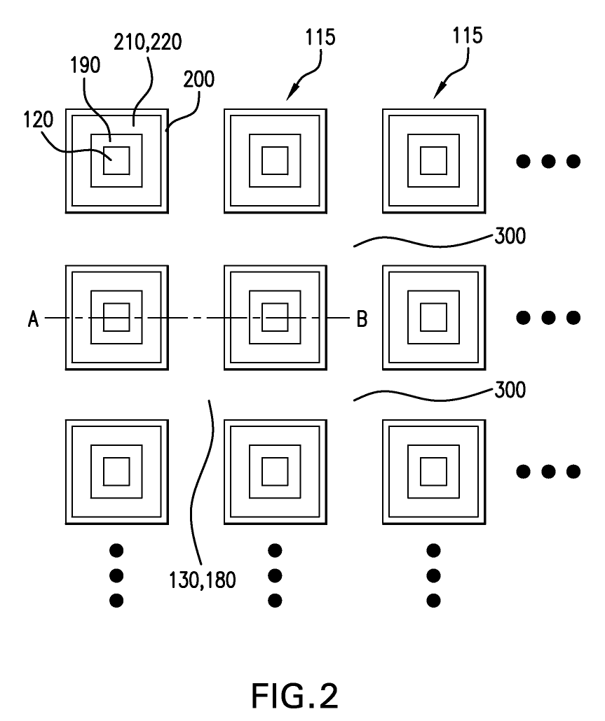

Referring to FIGS. 1 and 1a, a photovoltaic device 100 having a front and back orientation is shown schematically. The device 100 comprises a crystalline substrate 101 having a resistivity greater than about 0.02 ohm-cm. Over the substrate 101 is an epitaxy, thin-film layer 102. The thin-film layer 102 contacts the substrate in at least one region 104 to define a p-n junction 104a. To harness the electrical energy generated by the PV cell, front ohmic contacts 107 are electrically connected to the front of the cell 100, while a back ohmic contact 110 is electrically connected to the back. These elements are considered in detail below.

The substrate 101 has several important functions. First, it provides physical support for the thin-film layer 102. It may be the sole support for the thin-film layer or it may be used in combination with another substrate such a metal or ceramic layer to provide additionally rigidity. The substrate also forms the p-n junction 104a with the thin-film layer. The substrate of the present invention, however, also provides fault tolerance. As mentioned above, this fault tolerance facilitates the use of a thin-film epitaxy layer.

Fault tolerance is achieved by using a semiconductor with a resistivity greater than 0.01 ohm-cm. For example, it has been found that satisfactory fault tolerance is achieved when the resistivity of the substrate is greater than about 0.02 ohm-cm. Preferably, the resistively is greater than about 0.05 ohm-cm, and, more preferably, greater than about 0.1 ohm-cm.

Although greater resistivity tends to improve fault tolerance, at some point, the resistivity begins to impede the carrier flow through the p-n junction to the point that the voltage across the cell drops excessively. Thus, establishing the desired degree of resistivity in the substrate becomes an optimization of voltage across the cell versus fault tolerance. Fortunately, this is a wide window, meaning that the resistivity can be increased significantly without a corresponding drop in voltage. It has been found that suitable voltages are provided up to a resistivity of about 1 ohm-cm.

It should be understood, however, that the resistivity of the substrate might be modified for particular application. For example, if the thin-film layer is of a higher quality, it may be satisfactory for the substrate to have a slightly lower resistivity (and less fault tolerance) in favor of a higher voltage. Alternatively, if the thin layer is problematic (defect prone), then it may be worthwhile to increase the resistivity of the substrate above the above values.

The substrate may be doped to be a p or an n-type substrate. Preferably, the substrate is doped to be a p substrate for a number of reasons. For example, there are certain advantages to having an n-type thin film as discussed below. Furthermore, since p-type material is less expensive than n-type, it makes sense to use the less expensive of the two in the higher bulk application. The substrate is preferably a p+ substrate. A p+ substrate is a known class of semiconductor materials typically p-type material with a resistance less than 0.1 ohm-cm. By way of contrast, p++ is a p-type material highly doped with a resistivity less than 0.001 ohm-cm.

Suitable semiconductor materials for the substrate include, for example, silicon, or a mixture of silicon and another semiconductor material with a higher melting point than silicon, such as silicon carbide (SiC). Alternate substrates include metallurgical-grade silicon, or a thin silicon layer on steel, which provides enhanced flexibility and electrical contact conduction.

Preferably, the semiconductor is silicon, which may be noncrystalline or multi-crystalline. Preferably, the material is multi-crystalline since such a structure can be produced in high volume using conventional casting techniques. The substrate also does not need to be of high purity. For example, device-grade silicon typically requires a purity of 6N (i.e., 99.9999%), while the purity demands for the substrate in the present invention application are much less, for example, from below 6N to 3N. Preferably, the purity is 4N, which is less than that required in most semiconductor applications.

Suitable p-type dopants are well known and include for example, boron, aluminum, gallium and indium. Generally, boron is preferred since it is naturally occurring in silicon, the preferred substrate material. The desired levels of doping can thus be achieved simply by not purifying the semiconductor to traditional levels. For example, suitable results have been achieved by using a multi-crystalline silicon doped with about 1-20 ppm boron. Preferably, the semiconductor is doped with about 5-15 ppm boron, and even more preferably, the semiconductor is doped to about 7-10 ppm.

In a preferred embodiment, the substrate is a 4N multi-crystalline silicon having a resistivity of greater than 0.1 ohm-cm. Such a material is preferred from the standpoint of performance, availability and cost.

The substrate should be thick enough to provide the desired stability and fault protection. Although the thickness of the substrate varies according to the application, suitable results have been achieved using a substrate of about 200 to about 700 μm.

As mentioned above, the substrate's fault tolerance facilitates the use of an epitaxial, thin-film layer 102. As used herein, the term “thin-film layer” refers to a layer of semiconductor material deposited using known chemical and physical deposition techniques to a thickness no greater than about 50 μm. As is well known, epitaxial growth describes an ordered crystalline growth on a crystalline substrate. Epitaxial films may be grown from gaseous or liquid precursors. Because the substrate acts as a seed crystal, the deposited film takes on a lattice structure and orientation identical to those of the substrate.

Epitaxially-grown, thin-film layers have a number of advantages over bulk silicon. First, they are very efficient due to the close proximity of the charge carriers to the p-n junction. Additionally, thin-films use less material and typically require less time to form. Although thinner films tend to be more susceptible to defects such as voids, holes, crystalline boundaries, faults and manufacturing variances in thickness and consistency, these problems are mitigated by the fault tolerant substrate.

Traditional epitaxial growth techniques can be used including chemical vapor deposition or liquid deposition. Chemical vapor deposition (CVD) is a chemical process used to produce high-purity, high-performance solid materials. In a typical CVD process, the wafer (substrate) is exposed to one or more volatile precursors, which react and/or decompose on the substrate surface to produce the desired deposit. Frequently, volatile byproducts are also produced, which are removed by gas flow through the reaction chamber. Below is an example of the various CVD techniques that can be used:
Atmospheric pressure CVD (APCVD)—CVD processes at atmospheric pressure.
Low-pressure CVD (LPCVD)—CVD processes at subatmospheric pressures. Reduced pressures tend to reduce unwanted gas-phase reactions and improve film uniformity across the wafer.
Ultrahigh vacuum CVD (UHVCVD)—CVD processes at a very low pressure, typically below 10-6 Pa (˜10-8 torr).
Aerosol assisted CVD (AACVD)—A CVD process in which the precursors are transported to the substrate by means of a liquid/gas aerosol, which can be generated ultrasonically.
Direct liquid injection CVD (DLICVD)—A CVD process in which the precursors are in liquid form (liquid or solid dissolved in a convenient solvent). Liquid solutions are injected in a vaporization chamber, vaporized, and transported to the substrate as in classical CVD process. This technique is suitable for use on liquid or solid precursors. High growth rates can be reached using this technique.
Plasma methods
Microwave plasma-assisted CVD (MPCVD)
Plasma-Enhanced CVD (PECVD)—CVD processes that utilize a plasma to enhance chemical reaction rates of the precursors. PECVD processing allows deposition at lower temperatures.
Remote plasma-enhanced CVD (RPECVD)—Similar to PECVD except that the wafer substrate is not directly in the plasma discharge region. Removing the wafer from the plasma region allows processing temperatures down to room temperature.
Atomic layer CVD (ALCVD)—Deposits successive layers of different substances to produce layered, crystalline films.
Hot wire CVD (HWCVD) (also known as Catalytic CVD (Cat-CVD) or hot filament CVD (HFCVD))—Uses a hot filament to chemically decompose the source gases.
Metalorganic chemical vapor deposition (MOCVD)—CVD processes based on metalorganic precursors.
Rapid thermal CVD (RTCVD)—CVD processes that use heating lamps or other methods to rapidly heat the wafer substrate. Heating only the substrate rather than the gas or chamber walls helps reduce unwanted gas phase reactions that can lead to particle formation.
Vapor phase epitaxy (VPE)—generally any process that is not LPE or growth from molten silicon.

In addition to CVD, the thin-film layer may be grown by liquid phase epitaxy (LPE), which is a method to grow semiconductor crystal layers from a melt on solid substrates. This happens at temperatures well below the melting point of the deposited semiconductor. The semiconductor is dissolved in the melt of another material. At conditions that are close to the equilibrium between dissolution and deposition the deposition of the semiconductor crystal on the substrate is slowly and uniform. The growth of the layer from the liquid phase can be controlled by a forced cooling of the melt.

Another class of growth is growth from molten silicon by depositing a layer of silicon, melting it, and then growing silicon crystals—either epitaxially or on a dissimilar substrate. The initial silicon layer can be deposited by CVD, spraying, dipping, screen printing, etc. This layer is then heated to its melting point (possibly using an optical furnace which can focus the heat on the top layer). The crystals are grown when the molten silicon is cooled. It should be recognized that this method is hard to control on a silicon based substrate since the substrate and interfaces will also tend to melt.

In one embodiment, the thin-film layer 102 is grown over other planar elements on the substrate 101, such as an optical reflector 108. This requires that the thin film be grown laterally from the seed area (i.e., the p-n junction) to cover the reflector or barrier.

This requirement can be met using low temperature epitaxial lateral overgrowth (ELO) of silicon as discussed in G. W. Neudeck et al., Three Dimensional Devices Fabricated by Silicon Epitaxial Lateral Overgrowth, Journal of Electronic Materials, Col. 19, No. 10, 1990 (incorporated herein by reference). This method provides an active layer with high mobilities, large minority carrier lifetimes, and does not damage underlying active substrate since the processing temperatures are usually less than 1000° C. To produce ELO, seed windows (i.e., p-n junctions 104a) are opened on the substrate 101. Epitaxial growth is initiated selectively in the seed windows and progresses vertically until the level of the reflector 105 or barrier 108 is reached. Continuing to grow, the epitaxy will go laterally over the planar element producing a single crystalline silicon layer available for further device processing.

Preferably, the thin-film layer is epitaxially formed by CVD and even more preferably by ELO if planar elements, such as barriers and reflectors, are disposed on said substrate. Since the substrate is fault tolerant, manufacturing techniques can be used which favor high output and large surface areas, rather than precision and uniformity.

Suitable semiconductor materials for the thin-film include, for example, silicon, III-V compounds and II-VI compounds. Preferably, the thin-film material is silicon. Since the layer is thin, 5N purity is acceptable, although 6N or greater is desirable.

The thin-film layer by be doped type p or type n depending on application. Suitable dopants include, for example, boron for p-type and phosphorus for n-type.

As mentioned above, preferably, the substrate is p-type and the thin film is n-type. Among the other reasons for this preference already mentioned, it has been found that an n-type thin film is generally easier to passivate (which lowers the surface recombination potential and leads to higher efficiency). In this regard, in certain applications it may be preferable to passivate the top of the thin-film layer to form a passivated surface 106. This is a well known technique described in detail below.

Thickness of the thin-film layer can vary according to the application. Generally, it is preferred to make the layer thin to reduce the distance from the p-n junction, thereby eliminating the opportunity for the charge carriers to recombine. If the layer is too thin, however, the inevitable defects characteristic of a lower-tier, CVD, epitaxy layer become a more substantial component of the overall mass, thus leading to more ground faults. Suitable results have been achieved using a thin-film layer of about 5 to about 50 μm. Preferably, the thickness of the thin-film layer is about 5 μm to about 25 μm, and more preferably from about 5 μm to about 10 μm.

To enhance performance of the cell, it may be preferable to use light-capturing optics, such as reflectors 105 and a textured surface 109, to convert more photons to charge carriers, and isolating barriers 108 to limit the size of the p-n junctions 104a to increase the voltage across the cell (see FIG. 1a).

Light-capturing optics are discussed in Duerinckw et al., Optical Path Length Enhancement for >13% Screenprinted Thin Film Silicon Solar Cells, Presented at the 21 st European Photovoltaic Solar Energy Conference, Dresden, Germany, Sep. 4-7, 2006, which is herein incorporated by reference. It is preferred to texture the front surface 109, not only to decrease the front surface reflection, but also to increase the optical path length in the thin-film layer by scattering the light at an oblique angle. Ideally, the surface should be a lambertian refractor. In practice, it has been found that complete light scattering can be achieved for a Si removal of only 1.75 μm. However, since the epitaxial layer is quite thin, the silicon removal during the texturing step should be carefully controlled. If only a very limited amount of silicon is removed (short texturing) then the specular reflective component increases at higher wavelengths thereby limiting the diffusive behavior. A longer texturing rectifies this problem at the cost of more silicon being removed. Consequently, a compromise must be made between light scattering and the absorption volume of the epitaxial layer. A good uniform texturing is achieved with a limited removal of about 0.5 to about 1.0 μm, even though a lambertian surface texture (100% diffusive) is not quite achieved. Fluorine based plasma texturing has been found to achieve these objectives.

In addition to surface texturing, it is also preferable to employ reflectors to decrease the transmittance of long wavelength light into the substrate. Specifically, by positioning a reflector at the epi/substrate interface, photons that reach this interface are reflected and pass a second time through the thin-film layer. Since the light is preferably diffuse from the moment it entered the cell (due to the lambertian nature of the plasma texture mentioned above), a large part of photons will strike the front surface outside the escape angle. Therefore, most the photons will be reflected back down toward the substrate due Total Internal Reflectance (TIR). The photons continue to reflect between the reflector and the textured surface so that multiple passes through the epitaxial layer become possible.

In one embodiment, the reflector is made by electrochemical growth of a porous silicon stack of alternating high and low porosity layers (a multiple Bragg reflector). This process is described in detail in Duerinckw et al. During the epitaxial growth on top of the porous Si stack, the individual layers reorganize into Quasi Monocrystalline Silicon (QMS). The nanoporous layers are transformed into thin silicon layers with large voids, although the original layout of the stack is maintained. According to Duerinckw et al., this process is driven by minimization of surface energy. The result is alternating layers consisting of small and large voids. This structure tends to be suitable as a reflector due to constructive interference.

As mentioned above, the voltage across the PV cell can be increased by decreasing the size of the p-n junction relative to the area of the photon-collecting, thin-film layer 102. To this end, insulating barriers 108 are disposed on the substrate to define first regions 104 in which the thin-film layer contacts the substrate (i.e., the p-n junctions) and second regions in which the thin-film layer is isolated from the substrate. Preferably, the barriers cover a majority of said substrate to define p-n junctions over a minority portion of said substrate. In a preferred embodiment, the second regions comprise at least about 80% of the substrate surface area, and, more preferably about 95 to about 99%.

Although not necessary, it is usually preferable to depose the barriers in a periodic fashion to produce a pattern of p-n junctions/first regions. For example, as shown in FIG. 1, the first regions are defined as parallel rows. Alternatively, the second region may encompass a first region, to define the first regions as discrete shapes (e.g., round or polygonal). In any event, preferably, the distance between centers of any two adjacent first regions is less than a minority carrier diffusion length in the thin-film layer. For example, in an n-type thin film this length would be from about 10 μm to about 100 μm. Thus, in a preferred embodiment, the centers of the first region are no greater than about 5 μm to about 50 μm apart.

Alternately a thin (e.g., 0.01 to 1.0 microns) p-layer may be grown over the barrier to overcome the diffusion length limitations. This p-layer converts the generated minority carriers to majority carriers, which then are readily transported to the p-n junctions. Alternatively, rather than growing a p-type layer over the barrier, an n-type layer may be grown over the p-type barrier such that the p-type dopant in the barrier diffuses into the initial n-type layer to render it a p-type layer. In one embodiment, this initial n-type layer is grown separately from the thin-film layer, and, in another embodiment, it is the thin-film layer.

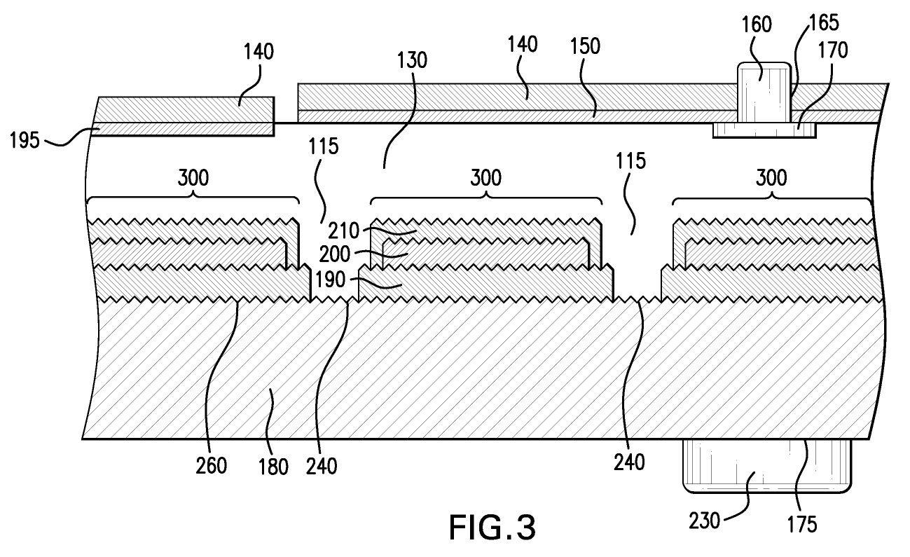

Referring to FIGS. 2-4, a particular embodiment of the PV cell and steps for manufacturing it are considered in detail. It should be understood that this particular embodiment is for illustrative purposes only, and that other embodiments may be practiced within the scope of the claims.

FIG. 2 shows a plan view of a first embodiment of a front-surface-illuminated photovoltaic device. An array of first regions 115 is laterally intermixed with second regions 300 where, in this embodiment, second regions 300 are the space between first regions 115. The first regions 115 have the shape of a square. Alternatively, first regions 115 could have the shape of any closed, bounded regions, such as polygons or circles, or they could be stripes extending laterally across the device. First regions 115 could also have varied shapes over the device, such as a mixture of bounded regions and stripes. In this embodiment, the first regions 115 (and concurrently second regions 300) are defined by holes formed through multiple layers, as explained in more detail below. FIG. 2 shows a corner of the device; first regions 115 extend in two dimensions laterally over the device, as indicated by the triplets of dots.

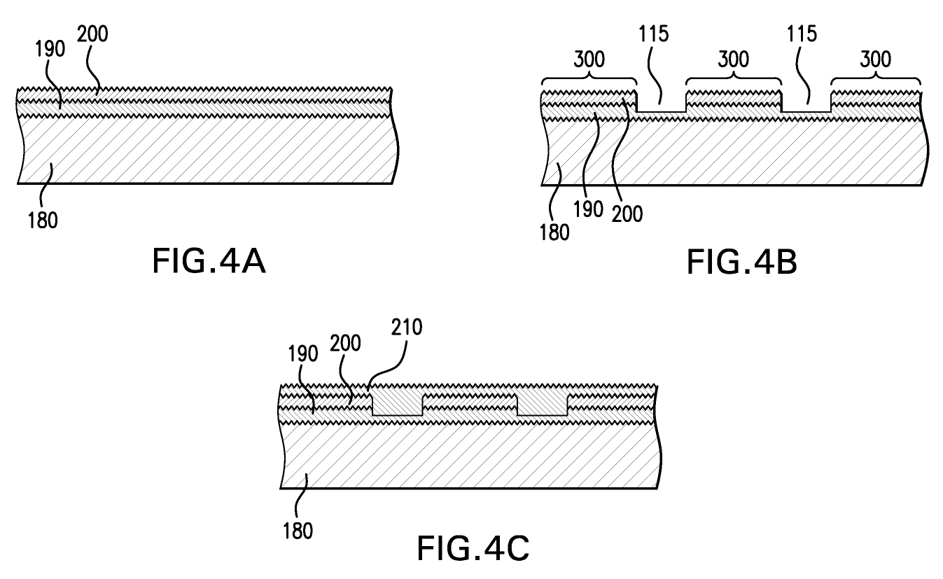

FIG. 3 shows a cross section of the structure of a first embodiment of a front-surface-illuminated photovoltaic device. The cross section is taken along the line A-B in FIG. 2. The device structure contains the following elements: a substrate 180 with a back surface; a thin-film layer 130, of doping type opposite to that of substrate 180 and having a front surface; a barrier layer 190 in contact with the substrate 180; a reflector layer 200 in contact with the barrier layer 190; at least one front-surface ohmic contact 160 for electrical contact to the thin-film layer 130; and at least one back surface ohmic contact 230 for electrical contact to the substrate 180.

Still referring to FIG. 3, the first regions 115 contain essential p-n junctions 240 for operation of the photovoltaic device. The p-n junctions 240 may be formed at the junction between the substrate 180 and the oppositely doped thin-film layer 130. The second regions 300 contain barrier layer 190 and reflector layer 200. Barrier layer 190 acts as a barrier to diffusion of impurities from substrate 180 into the rest of the device. Barrier layer 190 may enable the use of a lower purity (hence less expensive) material for the substrate 180. Barrier layer 190 also restricts carrier flow between the substrate and the thin-film layer. Reflector layer 200 acts to reflect photons entering the front surface back into thin-film layer 130 if those photons penetrate all the way to the reflector layer 200 without being absorbed in the thin-film layer 130. The presence of reflector layer 200 may therefore increase the efficiency of the device by making it more likely that a photon will be absorbed in thin-film layer 130, thus producing more electron-hole pairs that can be collected and contribute to the generated current.

As an option, as shown in the embodiment in FIG. 3, there may be an internal passivation layer 210 at least partially encapsulating reflector layer 200 in second regions 300. Internal passivation layer 210 is meant to prevent diffusion of the material of reflector layer 200 into the rest of the device. In the embodiment shown in FIG. 3, passivation layer 210 and barrier layer 190 completely encapsulate reflector layer 200, with passivation Layer 210 wrapping around the edges of reflector layer 200. Alternatively, passivation layer 210 may at least partially encapsulate barrier layer 190 by extending over the edges of barrier layer 190. Alternatively, if the material of reflector layer 200 is unlikely to diffuse significantly into the rest of the device during the processing of the device, internal passivation layer 210 may be omitted.

The device may have front passivation on the front surface to reduce recombination over the front surface and, in general, stabilize the electrical characteristics of the device. The front passivation may be made of at least one of the following: a front passivation layer 150, a floating p-n junction 100, or a heteroface. It could be formed, for example, by deposition of n-type GaP on the top surface of a p-type silicon thin-film layer 130. Floating junction 100 may be formed by diffusion of dopant into thin-film layer 130, the dopant of opposite type to that of thin-film layer 130.

The device may have an anti-reflection coating 140 covering front passivation layer 150 and floating junctions 195. Anti-reflection coating 140 decreases the fraction of incident light reflected from the front surface and therefore improves overall conversion efficiency of the device.

Electrical contact is made to the device using at least one front ohmic contact 160 to thin-film layer 130 and at least one back ohmic contact 230 to substrate 180. An additional doping layer (not shown) may be added to substrate 180 at back contact interface 175 to decrease contact resistance. Alternatively, separate doping for the back contact 230 may not be required; the doping of the substrate 180 may be sufficiently high to give an ohmic contact without additional doping at interface 175. In one embodiment, the doping of the substrate can be as high as it needs to be to get good ohmic contact with the deposited back contact metal 230. There would not be a need for a diffused or alloyed layer at the interface 175. For the front ohmic contact 160, additional doping layer 170 may be formed in thin-film layer 130 to reduce recombination at the front contact. For example, if the thin-film layer 130 is n-type, an n+ layer may be fabricated under the contacts. Front passivation layer 150, a heteroface, or a floating junction 100 reduces recombination across the rest of the front surface.

The front contact 160 may be buried. In an embodiment in which internal passivation layer 210 is not present, and reflector layer 200 is a good electrical conductor, such as a metal, an electrical connection may be established from front metal contact 160 to reflector layer 200 by using a heavily doped vertical layer (not shown).

Barrier layer 190, reflector layer 200, and internal passivation layer 210 add front to a total thickness between about 0.1 and about 0.5 micrometers. Barrier layer 190 material may be a nitride of silicon, an oxide of silicon, an oxide of aluminum, aluminum nitride, tungsten carbide, titanium carbide, or silicon carbide. Reflector layer 200 should have high reflectivity at light wavelengths close to the bandgap absorption wavelengths of the semiconductor material of thin-film layer 130. Reflector layer 200 may be a metal or a non-metal. If thin-film layer 130 is primarily silicon, appropriate metals for reflector layer 200 include nickel silver, chrome, palladium or any combination thereof. Appropriate non-metals include titanium nitride, boron carbide, silicon carbide, or any combination thereof. Internal passivation layer 210 may be a nitride of silicon, an oxide of silicon, a carbide of silicon, or any combination thereof. Internal passivation layer 210 may also be a wide bandgap material, such as silicon carbide (SiC) which may form a high-low semiconductor junction with seed layer 220 or directly with thin-film layer 130.

Front passivation layer 150 may be made of amorphous silicon, a nitride of silicon, or an oxide of silicon, or a combination of these.

Anti-reflection coating 140 may have a single layer or multiple layers of materials which are at least partially transparent to light in the range of wavelengths from the infra-red through the ultraviolet and which have appropriate indices of refraction and thicknesses. Suitable materials include, but are not limited to, a nitride of silicon, an oxide of titanium, an oxide of tantalum, an oxide of aluminum, an oxide of silicon, or any combination thereof.

The thickness of thin-film layer 130 in this embodiment is between about 2 and about 50 micrometers.

In operation, photons enter the device through the front surface. Photons may be absorbed directly in thin-film layer 130. Some photons, especially those of longer wavelength, may pass completely through thin-film layer 130 to reflector layer 200 without being absorbed. They may then be reflected back into thin-film layer 130 and absorbed. If substrate 180 has a textured surface 260, reflector layer 200 may also have a textured surface, and photons striking reflector layer 200 will be scattered as well as reflected, increasing the optical path length and the likelihood of absorption in thin-film layer 130. Photons may also pass through to textured surface 260 of substrate 180 in the first regions 115 where they are scattered back into thin-film layer 130 and then absorbed. Once a photon is absorbed, an electron-hole pair is formed and the two carriers thermally diffuse. Carriers reaching depletion regions of p-n junctions 240 will be swept out, or collected, by the built-in electric fields of junctions 240 and contribute to external photocurrent.

For good efficiency of carrier collection, distances between openings defining first regions 115 should be small enough that carriers are collected before they recombine. One way this may be achieved is to make lateral distance between centers of any two adjacent first regions 115 less than one minority carrier diffusion length in thin-film layer 130. In general, the distance between openings defining first regions 115 and/or the sizes of the openings may be chosen to optimize efficiency for a given diffusion length (or carrier lifetime) in thin-film layer 130. For a silicon device, it is expected that the distance between centers of first regions 115 will fall in the range from about 2 to about 1000 micrometers, and the width of first regions 115 is expected to fall in the range from about 1 to about 50 micrometers.

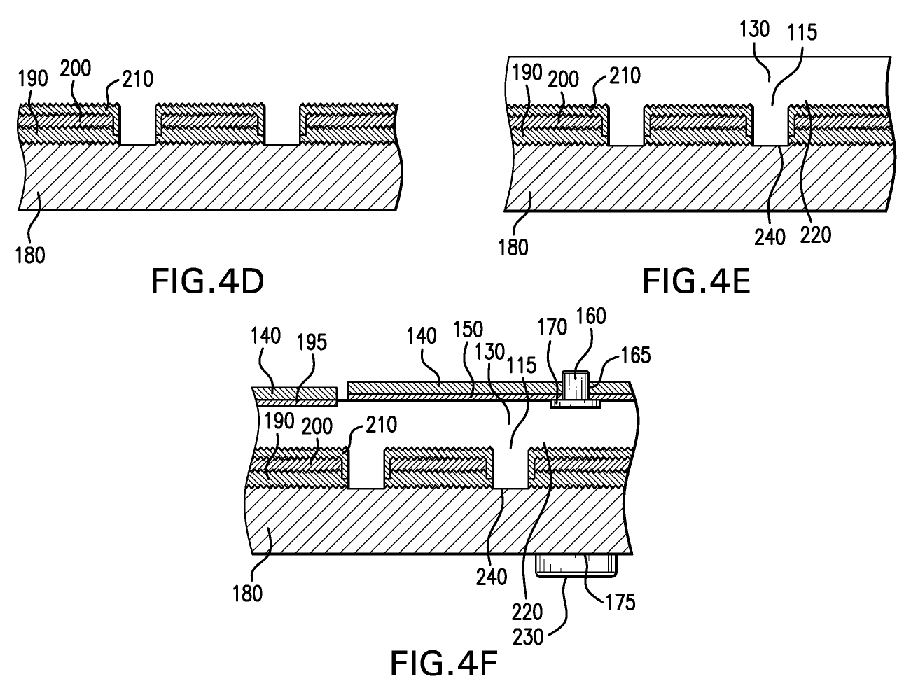

FIGS. 4A-F show an embodiment of a process for fabricating the embodiment of a solar photovoltaic device shown in FIGS. 2 and 3. FIG. 4A shows the device structure after the steps of obtaining a semiconductor substrate 180 of a first doping type with a top and bottom surface; forming barrier layer 190 on the top surface; and depositing reflector layer 200 on barrier layer 190. Prior to the forming of barrier layer 190, substrate 180 may be textured to enhance light scattering from the top surface of substrate 180 back into thin-film layer 130, as disclosed above. The texturing can be achieved by texturing a mold in which substrate 180 is cast. Alternatively, texturing may be achieved by forming a mixture of the semiconductor material of substrate 180 and particles of a thin-film having a melting point higher than that of the material of substrate 180; heating the mixture to a temperature above the melting point of the substrate and below the melting temperature of the thin-film, and cooling the mixture below the melting point of the substrate. The particles impart texture to substrate 180. As a specific example, substrate 180 is silicon and silicon carbide (SiC), and the proportion of silicon carbide, by volume, is in the range from about 1% to about 90%. The particles may have sizes in the range from about 0.1 to about 1.0 micrometers. The texturing is configured to scatter light in the wavelength range from the infrared to the ultraviolet.

Barrier layer 190 and reflector layer 200 may be formed using any known deposition technique including, but not limited to, APCVD, LPCVD, PECVD, MOCVD, or other chemical vapor deposition methods; evaporation; sputtering; spray pyrolysis; or printing. Barrier layer 190 may be formed using thermal oxidation.

FIG. 4B shows the structure after a step of forming a plurality of openings through reflector layer 200 and barrier layer 190. The openings define a plurality of first regions 115 and the spaces separating the openings define second regions 300. The openings may be formed using known techniques including, but not limited to, wet chemical etching; dry etching, such as plasma etching; laser machining; air abrading; or water blasting. If the surface of substrate 180 is textured, openings may be formed through thinning layers on surface-textured peaks: the reflector and barrier layers will be thinner over the peaks of the texture than over the valleys, and these thinner regions can be etched away, exposing the underlying substrate 180, while leaving the substrate 180 covered in the thicker regions. Some of these methods, such as wet or dry etching, may require a masking step, such as photolithography using photoresist. Others, such as laser machining, may not require a masking step.

FIG. 4C shows the structure after a step of depositing internal passivation layer 210 covering reflector layer 200. Passivation layer 210 may be deposited using chemical vapor deposition, sputtering, spray pyrolysis, or printing.

FIG. 4D shows the structure after completion of a step of completing the forming of openings defining first regions 115 by forming a plurality of openings in internal passivation layer 210 coinciding with the openings defining the first regions, such that the remaining internal passivation layer 210 at least partially encapsulates the reflector layer 200 at edges of the second regions. A patterned photoresist layer may be used to define the areas to be etched. Alternatively, barrier layer 190 may be partially encapsulated by passivation layer 210 as well. In this step, the top surface of substrate 180 is exposed. Openings in passivation layer 210 may be formed using any of the techniques disclosed above in connection with FIG. 4B.

FIG. 4E shows the structure after a step of depositing semiconductor thin-film layer 130 covering first regions 115 and second regions 300 and forming p-n junctions 240 inside the openings defining first regions 115.

As discussed above, epitaxially depositing the semiconductor layer may be carried out using liquid or chemical vapor deposition (CVD), preferably CVD. As one example, trichlorosilane may be used in the CVD step to deposit silicon thin-film layer 130. Prior to CVD deposition, substrate 180 may be cleaned using known techniques, such as an etch with HCl. This step could be done in-situ in a CVD reactor. Thin-film layer 130 may have acceptable electronic properties as deposited. As mentioned above, to grow the thin-film layer is grown epitaxially over the reflector 200 (and passivation layer 210)

FIG. 4F shows the structure after the steps of forming one or more ohmic contacts to thin-film layer 130 and to substrate 180; also front passivation layer 150, floating junction 100, and anti-reflection coating 140. Ohmic contact to thin-film layer 130 contains metal 160 and additional doping layer 170 in thin-film layer 130 to reduce recombination. Doping layer 170 may be formed by diffusion, ion implantation, or other known techniques. Ohmic contact to substrate contains metal 230 in contact with substrate 180 at back contact interface 175. Optionally, additional doping may be introduced at interface 175, similar to layer 170. Ohmic contacts to thin-film layer 130 may be formed by depositing passivation layer 150 and anti-reflection coating 140, then forming openings 165 through both of these layers. Metal 160 is deposited and patterned using known techniques. Alternatively, forming ohmic contacts to thin-film layer 130 may include screen printing metal 160, such as silver, on front passivation layer 150 and firing the metal through passivation layer 150. Alternatively, metal 160 may be fired through anti-reflection coating 140 if metal 160 is applied before contact openings 165 are formed.

Front passivation layer 150 may be deposited using any of the deposition techniques disclosed above in the description of FIG. 4A. Front passivation layer 150 may form a hetero-junction (an electrical junction between dissimilar semiconductor materials) with thin-film layer 130.

Before deposition of passivation layer 150, the front surface of thin-film layer 130 may be textured, either mechanically, chemically, or with a combination of these methods, to reduce front surface reflectance.

In an alternative embodiment, the device has substrate 180, thin-film layer 130 of opposite doping type to the substrate 180 and deposited on substrate 180, at least one ohmic contact 160 to the thin-film layer, and at least one ohmic contact 230 to substrate 180. As in previously described embodiments, this embodiment may also have front passivation, single- or multiple-layer a reflection coating, and textured surfaces on the substrate and thin-film layers. Materials for these structures and methods for making this device may be as previously disclosed.

Applicants specifically incorporate the entire contents of all cited references in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

What is claimed:

1. A photovoltaic device having a front and back orientation and comprising:
a crystalline substrate having a resistivity greater than about 0.01 ohm-cm; and
an epitaxy thin-film layer in front of said substrate, said thin-film layer contacting said substrate in at least one region to define a p-n junction.

2. The device of claim 1, wherein said substrate has a resistivity greater than about 0.05 ohm-cm.

3. The device of claim 2, wherein said substrate is multi-crystalline, P+ silicon and said thin-film layer is n-type silicon.

4. The device of claim 3, wherein said substrate comprises about 1-20 ppm boron.

5. The device of claim 4, wherein said substrate has a purity of no greater than 4N.

6. The device of claim 1, wherein said substrate has a thickness of at least about 50 μm.

7. The device of claim 3, wherein said thin-film layer is formed through chemical vapor deposition.

8. The device of claim 1, wherein said thin-film layer has a thickness of no greater than about 50 microns.

9. The device of claim 1, further comprising:
a barrier layer between said substrate and said thin-film layer, wherein said barrier layer covers a majority of said substrate.

10. The device of claim 9, wherein said p-n junctions are periodic.

11. The device of claim 9, wherein said p-n junctions are a plurality of parallel stripes on the surface of said substrate

12. The device of claim 9, wherein said barrier layer cover no less than about 60% of said substrate

13. The device of claim 9, further comprising:
a reflector over said substrate for reflecting photons away from said substrate and back into said thin-film layer.

14. The device of claim 9, wherein said reflector is an insulator.

15. A method of producing a cell comprising:
(a) providing a crystalline substrate having a resistivity greater than about 0.01 ohm-cm; and
(b) epitaxially depositing a thin-film layer over at least a portion of said substrate.

16. The method of claim 15, wherein said depositing is performed using CVD.

17. The method of claim 15, wherein step (a) comprising casting said substrate.

18. The method of claim 17, wherein said casting comprises texturing the front surface of said substrate.

19. The method of claim 15, wherein said crystalline substrate is polycrystalline

20. The method of claim 19, wherein said substrate has boron at a concentration of about 1 to about 20 ppm.

21. The method of claim 15, wherein said thin-film layer is deposited over said substrate using chemical vapor deposition.

22. The method of claim 15, further comprising:
deposing a third layer over a portion of said substrate.

23. The method of claim 22, wherein said third layer is at least one of a barrier or a reflector.

24. The method of claim 23, wherein said third layer is a barrier and said method further comprises:
deposing a reflector over said barrier layer.

25. The method of claim 23, wherein said thin film layer is epitaxially grown over said third payer using ELO.

26. The method of claim 23, after said thin-film layer is deposited, texturing wherein the front surface of said thin-film layer.

27. The method of claim 23, further comprising creating a p-type layer over said third layer to increase diffusion length

28. The method of claim 23, wherein creating a p-type layer is formed by either depositing an intermediate p-type layer over said third layer, or allowing p-type impurities to diffuse into an n-type layer.

29. The method of claim 23, wherein said n-type layer is said thin-film layer.
